(19) United States
(12) Patent Application Publication
(10) Pub. No.: US 2020/0365761 A1
(43) Pub. Date: Nov. 19, 2020

(54) LIGHT-EMITTING DIODE AND METHOD FOR MANUFACTURING THE SAME

(71) Applicant: XIAMEN SAN'AN OPTOELECTRONICS CO., LTD., Xiamen (CN)

(72) Inventors: Chang-Cheng CHUO, Xiamen (CN); Shengchang CHEN, Xiamen (CN); Heqing DENG, Xiamen (CN)

(21) Appl. No.: 16/986,563

(22) Filed: Aug. 6, 2020

Related U.S. Application Data
(63) Continuation-in-part of application No. PCT/CN2019/073485, filed on Jan. 28, 2019.

(30) Foreign Application Priority Data
Feb. 12, 2018 (CN) 201810144122.6

(51) Int. Cl. H01L 33/12; H01L 33/00

(52) U.S. Cl. CPC H01L 33/12; H01L 33/0075; H01L 33/0025

(57) ABSTRACT

A light-emitting diode (LED) includes a substrate, an epitaxial layered structure, and a strain tuning layer. The epitaxial layered structure includes a buffer layer, an N-type cladding layer, an active layer, and a P-type cladding layer formed on the substrate in such order. The active layer includes a multiple quantum well structure. The strain tuning layer is disposed between the N-type cladding layer and the active layer, and has a lattice constant that is smaller than that of the N-type cladding layer. A method for manufacturing the LED is also disclosed.

### CROSS-REFERENCE TO RELATED APPLICATION

This application is a bypass continuation-in-part (CIP) application of PCT International Application No. PCT/CN2019/073485, filed on Jan. 28, 2019, which claims priority of Chinese Invention Patent Application No. 201310144122.6, filed on Feb. 12, 2018. The entire content of each of the International and Chinese patent applications is incorporated herein by reference.

### FIELD

This disclosure relates to a light-emitting diode and a manufacturing method thereof, and more particularly to a light-emitting diode which exhibits a reduced degree of bow, and a manufacturing method thereof.

### BACKGROUND

A light-emitting diode (LED) is a solid-state lighting device, which is first introduced in 1962, and which is made of semiconductor materials. At that time, LEDs could only emit red light having a relatively low luminance, and were only used in simple applications, such as signal lights and display panels. With advancement of technology, LEDs which can emit monochromatic lights having different colors have been developed. Until now, LEDs capable of emitting lights that have wavelengths within the visible light range, the infrared light range, and the ultraviolet (UV) light range and that have a significantly improved luminance, are widely used in various complicated applications, such as liquid crystal displays, decoration lights for televisions, lighting devices, and so on.

Among the currently available LEDs, an ultraviolet LED (UV LED) is capable of transforming electrical power directly into UV light. With the advancement of technology, UV LEDs have bright prospects in the biomedical field, identification of counterfeits, air or water purification, computer data storage, military, etc. In addition, UV LEDs have attracted increasing interest in the field of lighting, since the UV LEDs can excite phosphors having RGB colors to emit lights having different colors that are mixable with one another to form white light.

In recent years, the UV LEDs have replaced mercury lamps due to advantages such as increased power, elongated service life, and smaller size. In addition, the Minamata Convention on Mercury becomes effective in 2020, which may speed up large-scale application of the UV LEDs.

Referring to FIGS. 1 to 4, a conventional method for manufacturing an epitaxial structure of a UV LED usually includes the following steps:
1) providing a substrate 101 (see FIG. 1);
2) forming a buffer layer 102 made of aluminum nitride (AlN) on the substrate 101 (see FIG. 2);
3) forming an N-type cladding layer 103 made of aluminum nitride (AlGaN) on the buffer layer 102 (see FIG. 3); and
4) forming an active layer 104 on the N-type cladding layer 103, and forming a P-type cladding layer 105 made of AlGaN on the active layer 104 (see FIG. 4).

As shown in FIG. 3, a mismatch of lattice constants of the N-type cladding layer 103 and the buffer layer 102 might impose a lattice-mismatch-induced strain on the N-type cladding layer 103, and thus the epitaxial structure might be formed with a convex bow, which will result in uneven distribution of surface temperature of the active layer 104 during epitaxial growth (i.e., step 4), thereby adversely affecting a wavelength uniformity of light emitted from the resultant UV LED.

Therefore, there is still a need to develop a UV LED which is free of the convex bow, and a method for manufacturing the same.

### SUMMARY

Therefore, an object of the disclosure is to provide a light-emitting diode (LED) and a method for manufacturing the same that can alleviate or eliminate at least one of the drawbacks of the prior art.

According to the disclosure, the LED includes a substrate, an epitaxial layered structure, and a strain tuning layer. The epitaxial layered structure includes a buffer layer, an N-type cladding layer, an active layer, and a P-type cladding layer formed on the substrate in such order. The active layer includes a multiple quantum well structure. The strain tuning layer is disposed between the N-type cladding layer and the active layer, and has a lattice constant that is smaller than that of the N-type cladding layer.

According to the disclosure, the method for manufacturing the abovementioned LED includes the steps of:
a) sequentially forming the buffer layer and the N-type cladding layer on the substrate in such order, the buffer layer and the N-type cladding layer being formed with a bow due to a lattice-mismatch-induced strain;
b) forming the strain tuning layer on the N-type cladding layer opposite to the buffer layer, the strain tuning layer having a lattice constant smaller than that of the N-type cladding layer, so as to reduce the lattice mismatch-induced strain;
c) forming the active layer on the strain tuning layer opposite to the N-type cladding layer; and
d) forming the P-type cladding layer on the active layer opposite to the strain tuning layer.

### BRIEF DESCRIPTION OF THE DRAWINGS

Other features and advantages of the disclosure will become apparent in the following detailed description of the embodiments with reference to the accompanying drawings, in which:

FIGS. 1 to 4 are schematic views illustrating consecutive steps of a conventional method for manufacturing a conventional ultraviolet (UV) light-emitting diode (LED), in which an epitaxial structure formed thereby has a convex bow;

FIG. 5 is a flow chart illustrating a method for manufacturing a first embodiment of an LED according to the disclosure;

FIGS. 6 to 10 are schematic views illustrating consecutive steps of the method of FIG. 5, in which an epitaxial structure formed thereby has a greatly reduced degree of the convex bow;

FIG. 11 is a scanning electron microscopy image of the LED manufactured by the method according to the disclosure;

FIG. 12 is a schematic view illustrating a second embodiment of the LED according to the disclosure; and

FIG. 13 is a schematic view illustrating a third embodiment of the LED according to the disclosure.

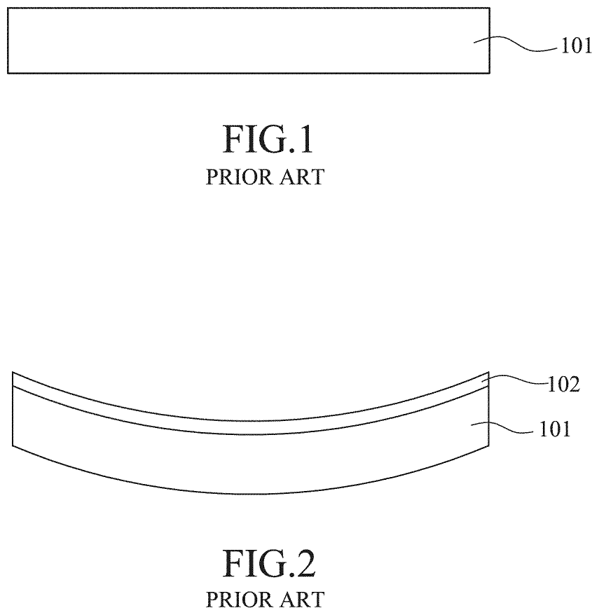

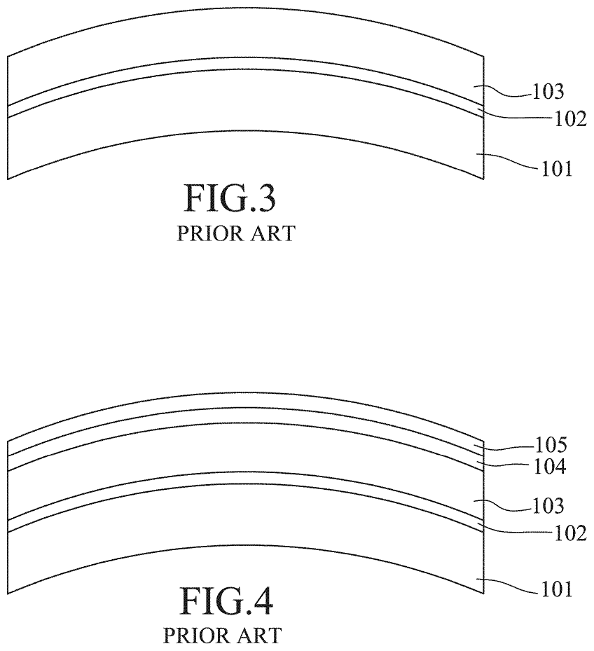

### DETAILED DESCRIPTION

Before the disclosure is described in greater detail, it should be noted that where considered appropriate, reference numerals have been repeated among the figures to indicate corresponding or analogous elements, which may optionally have similar characteristics.

Referring to FIG. 10, a first embodiment of a light-emitting diode (LED) according to the disclosure includes a substrate 201, an epitaxial layered structure 20, and a strain tuning layer 204.

The substrate 201 may be a flat substrate or a patterned substrate, and may be made of a material including, for example, but is not limited to, sapphire, silicon, silicon carbide (SiC), and gallium nitride (GaN). In this embodiment, the substrate 201 is a sapphire substrate.

The epitaxial layered structure 20 includes a buffer layer 202, an N-type cladding layer 203, an active layer 205, and a P-type cladding layer 207 formed on the substrate 201 in such order.

The buffer layer 202 may be made of an aluminum nitride (AlN)-based material. The N-type cladding layer 203 is configured to provide electrons for radiative recombination in the active layer 205, and may be made of an aluminum gallium nitride (AlGaN)-based material. The P-type cladding layer 207 is configured to provide electron holes. The active layer 205 is the main region in which electrons from the N-type cladding layer 203 and holes from the P-type cladding layer 207 undergo radiative recombination to emit light. For example, the active layer 205 is configured to emit light having an emission wavelength ranging from 210 nm to 320 nm (i.e., violet light).

When the lattice-mismatch-induced strain between the buffer layer 202 and the N-type cladding layer 203 is not relaxed, such strain may cause formation of a bow, which might result in a great deviation of surface temperature of the active layer 205, thereby lowering uniformity of light emitted from the resultant LED.

Therefore, the strain tuning layer 204 is disposed between the N-type cladding layer 203 and the active layer 205, and has a lattice constant that is smaller than that of the N-type cladding layer 203, so as to reduce the lattice-mismatch-induced strain, thereby improving light uniformity. In certain embodiments, the lattice constant of the strain tuning layer 204 is also smaller than those of the active layer 205 and the P-type cladding layer 206.

In this embodiment, the strain tuning layer 204 as made of a single material represented by AlₓGa_{y}In_{(1-x-y)}N, in which 0.7≤x≤1, 0≤y≤0.3, and 0.7≤(x+y)≤1, and has a thickness ranging from one atomic layer (e.g., 0.1 nm) to 100 nm. By formation of the strain tuning layer 204 made from a single material, the lattice-mismatch-induced strain can be reduced, while uniformity of electric current in the LED may also be improved.

Alternatively, the strain tuning layer 204 may be made of a plurality of materials represented by the chemical formula of AlₓGa_{y}In_{(1-x-y)}N, in which 0.70≤x≤1, 0≤y≤0.3, and 0.7≤(x+y)≤1, and the materials are different in at least one of x and y. In certain embodiments, x≥0.95. Example of the materials may include, but are not limited to, Al_{0.7}Ga_{0.3}In_{0.1}N, Al_{0.75}Ga_{0.3}In_{0.05}N, Al_{0.8}Ga_{0.15}In_{0.05}N, Al_{0.85}Ga_{0.1}In_{0.05}N, Al_{0.9}Ga_{0.05}In_{0.05}N, Al_{0.98}Ga_{0.01}In_{0.03}N, and combinations thereof. By flexibly controlling aluminum contents (i.e., x) and gallium contents (i.e., y) or the materials for making the strain tuning layer 204, a different degree of the bow can be reduced.

In certain embodiments, the strain tuning layer 204 is doped with an N-type dopant in a doping concentration ranging from 1×10¹⁷ cm⁻³ to 5×10¹⁶ cm⁻³. With such doping, a contact resistance between the strain tuning layer 204 and the N-type cladding layer 203 and that between the strain tuning layer 204 and the active layer 205 may be further lowered, thereby reducing heat generation of the epitaxial structure and reducing an amount of electric current required to be applied.

In certain embodiments, the strain tuning layer 204 directly contacts the N-type cladding layer 203 and the active layer 205, so as to more effectively tune and relax the strain between the N-type cladding layer 203 and the active layer 205, thereby reducing a degree of the bow.

The LED may further include an electron blocking layer 206 which is disposed between the active layer 205 and the P-type cladding layer (207). The electron-blocking layer 206 is configured to prevent the electrons in the active layer 205 from leaking into the P-type cladding layer 207, so as to improve a light extraction efficiency of the LED.

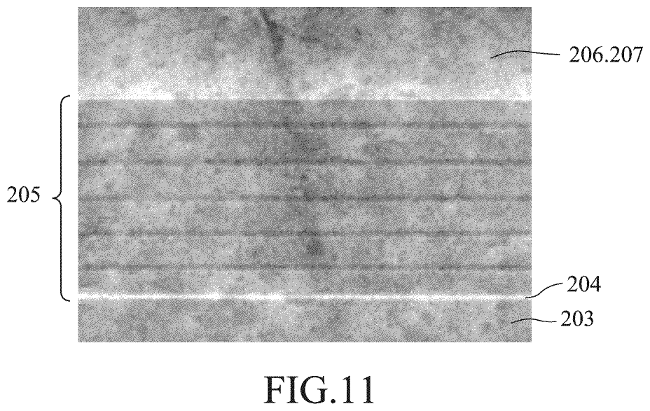

Referring to FIG. 11, a scanning electron microscopy (SEN) image of the first embodiment of the LED shows that, by introducing the strain tuning layer 204 between the N-type cladding layer 203 and the active layer 205, the bow formed due to the lattice-mismatch-induced strain may be flattened, thereby improving the quality of the active layer 205.

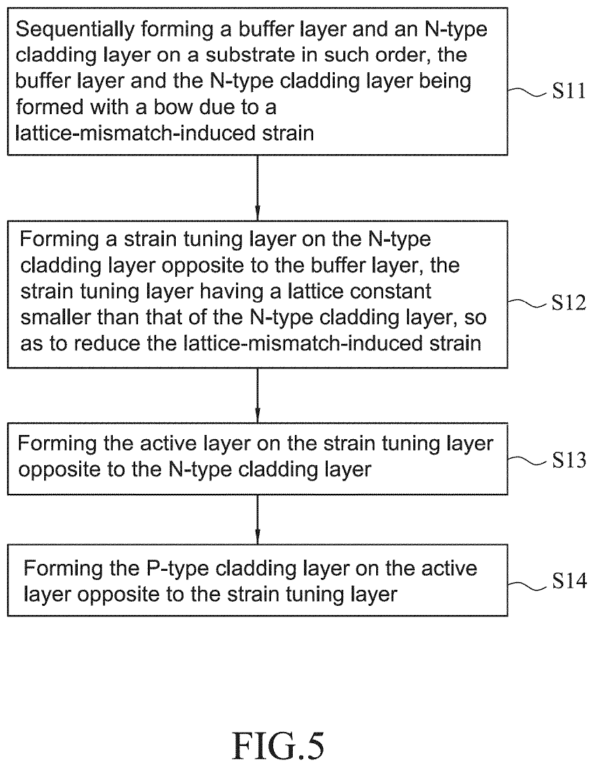

Referring to FIG. 5, a method for manufacturing the LED as mentioned above includes the following step S11 to S14.

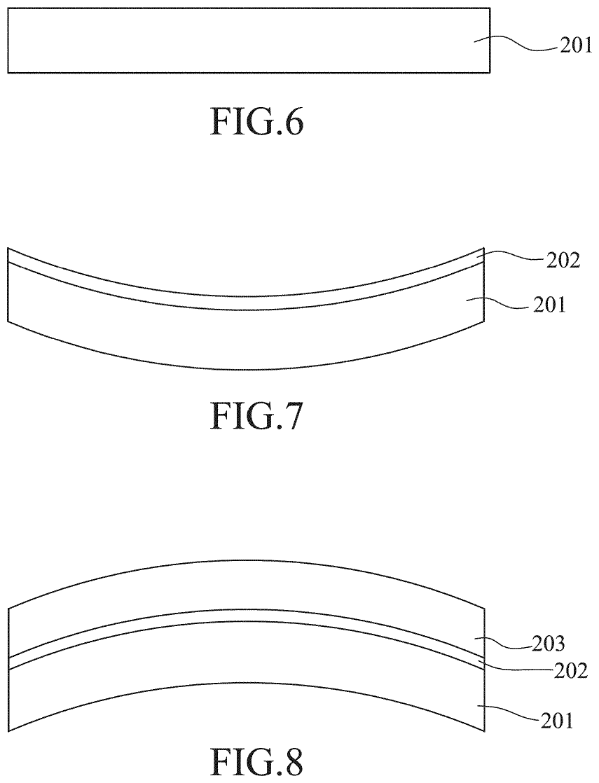

In step S11, referring to FIGS. 6 to 8, the buffer layer 202 and the N-type cladding layer 203 are sequentially formed on the substrate 201 in such order, in which the buffer layer 202 and the N-type cladding layer 203 are formed with a bow due to lattice-mismatch-induced strain.

To be specific, the buffer layer 202 made of an AlN-based material is formed on the substrate 201 using a metal organic chemical vapor deposition (MOCVD) process. As shown in FIG. 6, the buffer layer 202 and the sapphire substrate 201 are formed with a concave bow since the buffer layer 202 has a lattice constant smaller than that of the substrate 201. Then, the N-type cladding layer 203 made of an AlGaN-based material is formed on the buffer layer 202 using a chemical vapor deposition process. As shown in FIG. 7, the lattice mismatch between the buffer layer 202 and the N-type cladding layer 203 may induce a great strain, which causes formation of a bow, i.e., a convex bow. The N-type cladding layer 203 exhibiting the bow may have different thickness, leading to a deviation of the surface temperature of the active layer 205 to be formed thereon.

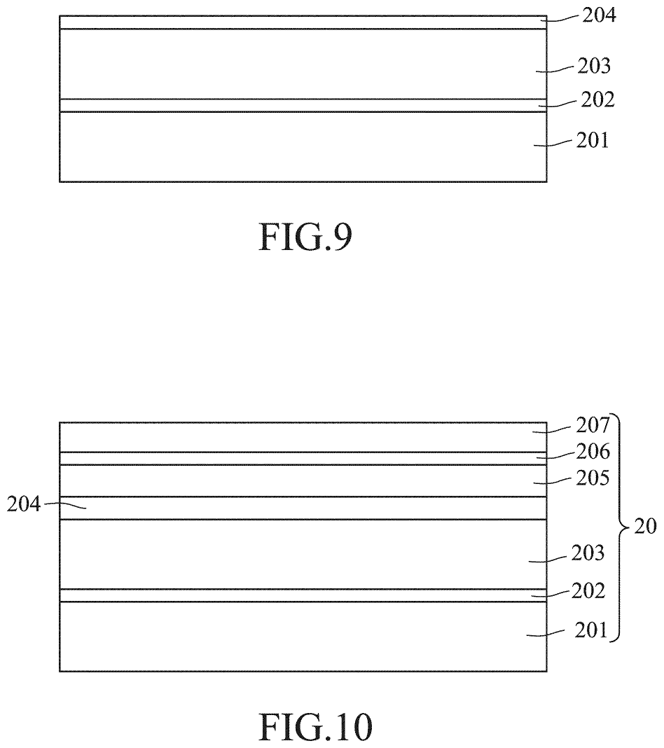

In step 612, referring to FIG. 9, the strain tuning layer 204, which made of a single material represented by the chemical formula of AlₓGa_{y}In_{(1-x-y)}N, and has a lattice constant smaller than that of the N-type cladding layer 203, is directly formed on the N-type cladding layer 203 opposite to the buffer layer 202 using a chemical vapor deposition process, so as to reduce the lattice-mismatch-induced strain. The growth temperature of the strain tuning layer 204 may range from 1100° C. to 1300° C. The lattice constant of the strain tuning layer 204 may be controlled by the flow rates of aluminum (Al), gallium (G) and indium (In) sources to be introduced. As shown in FIG. 9, since the convex bow formed in step S11 is flattened, the subsequent layers can be grown under substantially even surface temperature, thereby improving the quality of the epitaxial layered structure.

In step S13, referring to FIG. 10, the active layer 205 is directly formed on the strain tuning layer 204 opposite to the N-type cladding layer 203 using the MOCVD process. With the active layer 205, which is configured no emit light having a wavelength within the violet light range, cooperating with the strain tuning layer 204 made of AlₓGa_{y}In_{(1-x-y)}N, electrical properties of the epitaxial layered structure 20 affected by the strain tuning layer 204 may be minimized.

In step S14, referring to FIG. 9, the P-type cladding layer 207 is formed on the active layer 205 opposite to the strain tuning layer 204 using the MOCVD process. The method may further include, between steps S13 and S14, a step of forming the electron-blocking layer 206 on the active layer 205 using the MOCVD process, and then in step S14, the P-type cladding layer 207 is formed on the electron-blocking layer 206 opposite to the active layer 205.

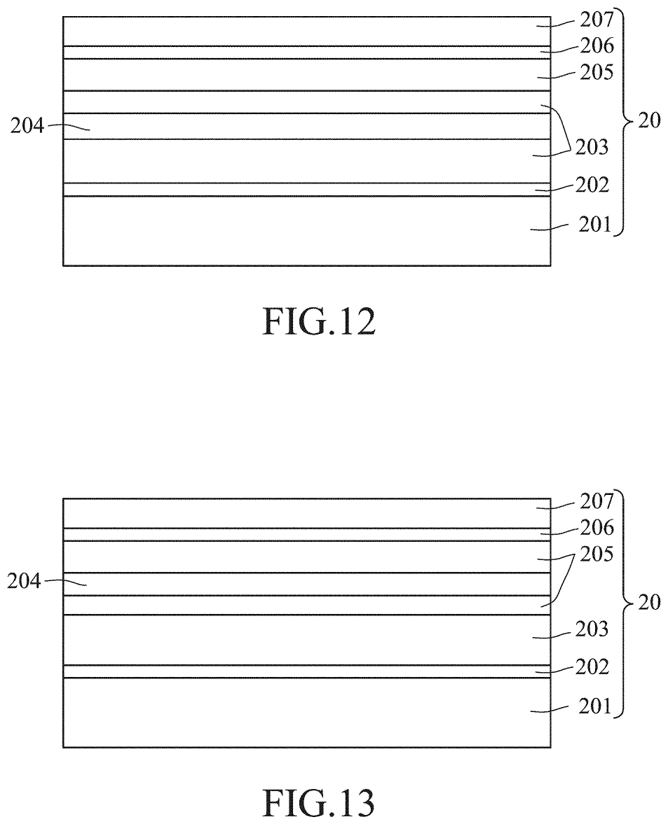

Referring to FIG. 12, a second embodiment of the LED according to the disclosure is similar to the first embodiment except that the strain tuning layer 204 of the second embodiment is disposed in the N-type cladding layer 203. To be specific, the N-type cladding layer 203 includes mu multiple sub-layers, and the strain tuning layer 204 is sandwiched between two of the sub-layers of the N-type cladding layer 203. Referring to FIG. 13, a third embodiment of the LED according to the disclosure is similar to the first embodiment except that the strain tuning layer 204 is disposed in the active layer 205. To be specific, the active layer 205 includes multiple sub-layers, and the strain tuning layer 204 is sandwiched between two of the sub-layers of the active layer 205.

In sum, by formation of the strain tuning layer 204, which is made of AlₓGa_{y}In_{(1-x-y)}N and which has an aluminum content of at least 70 mol %, be the N-type cladding layer 203 and the active layer 205, the degree of bow formed due to the lattice-mismatch-induced strain between the buffer layer 203 and the N-type cladding layer 205 may be greatly reduced, so as to prevent deviation of the surface temperature of the active layer 205 (i.e., achieving an even temperature distribution), thereby improving the wavelength uniformity of light emitted from the LED according to this disclosure

In the description above, for the purposes of explanation, numerous specific details have been set forth in order to provide a thorough understanding of the embodiments. It will be apparent, however, to one skilled in the art, that one or more other embodiments may be practiced without some of these specific details.

It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A light-emitting diode, comprising:
a substrate;
an epitaxial layered structure including a buffer layer, an N-type cladding layer, an active layer, and a P-type cladding layer formed on said substrate in such order, said active layer including a multiple quantum well structure; and
a strain tuning layer disposed between said N-type cladding layer and said active layer and having a lattice constant that is smaller than that of said N-type cladding layer.

2. The light-emitting diode according to claim 1, wherein the lattice constant of said strain tuning layer is smaller than those of said active layer and said P-type cladding layer.

3. The light-emitting diode according to claim 1, wherein said strain tuning layer is made of a plurality of materials represented by a chemical formula of AlₓGa_{y}In_{(1-x-y)}N, where 0.7≤x≤1, 0≤y≤0.3, and 0.7≤(x+y)≤1, said materials being different in at least one of x and y.

4. The light-emitting diode according to claim 1, wherein said active layer is configured to emit light which has an emission wavelength that ranges from 210 nm to 320 nm.

5. The light-emitting diode according to claim 1, wherein said buffer layer is made of aluminum nitride (AlN)-based material, and said N-type cladding layer is made of aluminum gallium nitride (AlGaN)-based material.

6. The light-emitting diode according to claim 1, wherein said strain tuning layer is made of a single material represented by a chemical formula of AlₓGa_{y}In_{(1-x-y)}N, where 0.7≤x≤1, 0≤y≤0.3, and 0.7≤x+y≤1, and has a thickness ranging from 0.1 nm to 100 nm.

7. The light-emitting diode according to claim 1 wherein said strain tuning layer directly contacts said N-type cladding layer and said active layer.

8. The light-emitting diode according to claim 1, wherein said strain tuning layer is doped with an N-type dopant in a doping concentration that ranges from 1×10¹⁷ cm⁻³ to 5×10¹⁹ cm⁻³.

9. The light-emitting diode according to claim 1, further comprising an electron blocking layer which is disposed between said active layer and said P-type cladding layer.

10. A method for manufacturing a light-emitting diode, comprising the steps of:
a) sequentially forming a buffer layer and an N-type: cladding layer on a substrate in such order, the substrate, the buffer layer and the N-type cladding layer being formed with a bow due to a lattice-mismatch-induced strain;
b) forming a strain tuning layer on the N-type cladding layer opposite to the buffer layer, the strain tuning layer having a lattice constant smaller than that of the N-type cladding layer, so as to reduce the lattice-mismatch-induced strain;
c) forming an active layer on the strain tuning layer opposite to the N-type cladding layer; and
d) forming a P-type cladding layer on the active layer opposite to the strain tuning layer.

11. The method according to claim 10, wherein the lattice constant of the strain tuning layer is smaller than those of the active layer and the P-type cladding layer.

12. The method according to claim 10, wherein the strain tuning layer is made of a plurality of materials represented by a chemical formula of AlₓGa_{y}In_{(1-x-y)}N, where 0.7≤x≤1, 0≤y≤0.3, and 9.7≤(x+y)≤1, the materials being different in at least one of x and y.

13. The method according to claim 10, wherein the active layer is configured to emit light having an emission wavelength that ranges from 210 nm to 320 nm.

14. The method according to claim 10, wherein in step b), the strain tuning layer is epitaxially formed at a growth temperature that ranges from 1100° C. to 1300° C.

15. The method according to claim 10, wherein in step a), the bow is a convex bow, and in step b), a degree of the convex bow is reduced.

16. The method according to claim 15, wherein the buffer layer is made of an aluminum nitride (AlN)-based material, and the N-type cladding layer is made of an aluminum gallium nitride (AlGaN)-based material.

17. The method according to claim 10, wherein the strain tuning layer is made of a single material represented by a chemical formula of AlₓGa_{y}In_{(1-x-y)}N, where 0.7≤x≤1, 0≤y≤0.3, and 0.7≤x+y≤1, and has a thickness ranging from 0.1 nm to 100 nm.

18. The method according to claim 10, wherein in step b), the strain tuning layer is directly formed on the N-type cladding layer, and in step c), the active layer is directly formed on the strain tuning layer.

19. The method according to claim 10, wherein the strain tuning layer is doped with an N-type dopant in a doping concentration that ranges from 1×10¹⁷ cm⁻³ to 5×10¹⁹ cm⁻³.

20. The method according to claim 10, further comprising, after step c) and before step d), a step e) of forming an electron-blocking layer on the active layer.
